(19) United States
(12) Patent Application Publication
(10) Pub. No.: US 2026/0090073 A1
(43) Pub. Date: Mar. 26, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Daiki YOSHIKAWA, Nonoichi Ishikawa (JP)

(21) Appl. No.: 19/067,795

(22) Filed: Feb. 28, 2025

(30) Foreign Application Priority Data
Sep. 20, 2024 (JP) 2024-164002

(51) Int. Cl. H10D 84/00

(52) U.S. Cl. CPC H10D 84/161

(57) ABSTRACT

A semiconductor device having a transistor and a diode, comprising: a semiconductor layer comprising first and second surfaces and first and second electrodes. The semiconductor layer comprises: a first region of a first conductivity type between the first and second surfaces; a second region of a second conductivity type between the first surface and the first region; a third region of the first conductivity type between the second region and the first surface, and electrically connected to the first electrode; a fourth region of the second conductivity type between the second surface and the first region, and electrically connected to the second electrode; a first trench contact electrically connected to the first electrode, penetrating through the second and third regions to reach the first region; a third electrode in a trench penetrating through the second and third regions to reach the first region, and covered by an insulating film.

### CROSS-REFERENCE TO RELATED APPLICATIONS

This application is based upon and claims the benefit of priority from Japanese Patent Application No. 2024-164002, filed on September 20, 2024, the entire contents of which are incorporated herein by reference.

### FIELD

Embodiments described herein relate generally to a semiconductor device.

### BACKGROUND

A semiconductor device known as a reverse-conducting insulated gate bipolar transistor (RC-IGBT) includes a transistor and a freewheeling diode connected in parallel to the transistor. In such a semiconductor device, the transistor is formed in the transistor region, and the diode is generally formed in the diode region. When the diode in the diode region conducts, an electron current flows from the cathode region to the anode region of the diode, and a hole current flows from the anode region to the cathode region.

However, since the base region of the transistor region is at the same potential as the anode region, holes are also injected from the transistor region. As a result, it takes longer for the carriers to disappear during the diode turn-off process.

### BRIEF DESCRIPTION OF THE DRAWINGS

FIG. 1 is a top schematic view of the semiconductor device according to the present embodiment.

FIG. 2 is a cross-sectional view along line AA' of FIG. 1.

FIG. 3 is a schematic cross-sectional view of a part of a semiconductor device according to a comparative example.

FIG. 4 is a schematic cross-sectional view of a part of a semiconductor device according to the second embodiment.

FIG. 5 is a schematic cross-sectional view of a part of a semiconductor device according to the third embodiment.

FIG. 6 is a schematic cross-sectional view of a part of a semiconductor device according to the fourth embodiment.

FIG. 7 is a schematic cross-sectional view of a part of a semiconductor device according to the fifth embodiment.

### DETAILED DESCRIPTION

Embodiments of the present invention will be described below with reference to the drawings. In the following description, the same or similar members are denoted by the same reference numerals, and the description of such members will be omitted as appropriate.

In this specification, when the notation n+ type, n type, or n- type is used, it means that the impurity concentration of the n type decreases in the order of n+ type, n type, and n- type. Similarly, when the notation p+ type, p type, or p- type is used, it means that the impurity concentration of the p type decreases in the order of p+ type, p type, and p- type.

In this specification, the distribution and absolute value of the impurity concentration in the semiconductor region can be measured using, for example, secondary ion mass spectrometry (SIMS). The relative magnitude of the impurity concentrations of two semiconductor regions can be determined using, for example, scanning capacitance microscopy (SCM). Additionally, the distribution and absolute value of the impurity concentration can be measured using, for example, spreading resistance analysis (SRA). SCM and SRA can determine the relative magnitude and absolute value of the carrier concentration in the semiconductor region. By assuming the activation rate of impurities, it is possible to determine the relative magnitude, distribution, and absolute value of the impurity concentration between two semiconductor regions from the measurement results of SCM and SRA.

### First Embodiment

The semiconductor device 100 of the first embodiment is, for example, an RC-IGBT in which an IGBT and a diode are formed on the same semiconductor chip.

The semiconductor device 100 according to this embodiment includes a trench gate type IGBT having a gate electrode formed in a trench formed in the semiconductor layer. Hereinafter, an example in which the first conductivity type is n type and the second conductivity type is p type will be described, but the first conductivity type may be p type and the second conductivity type may be n type. In this case, the conductivity types of the substrate, layers, regions, etc., in each embodiment will be of opposite polarity.

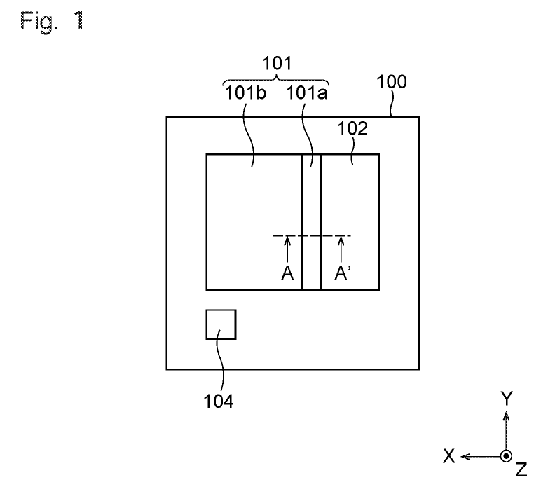

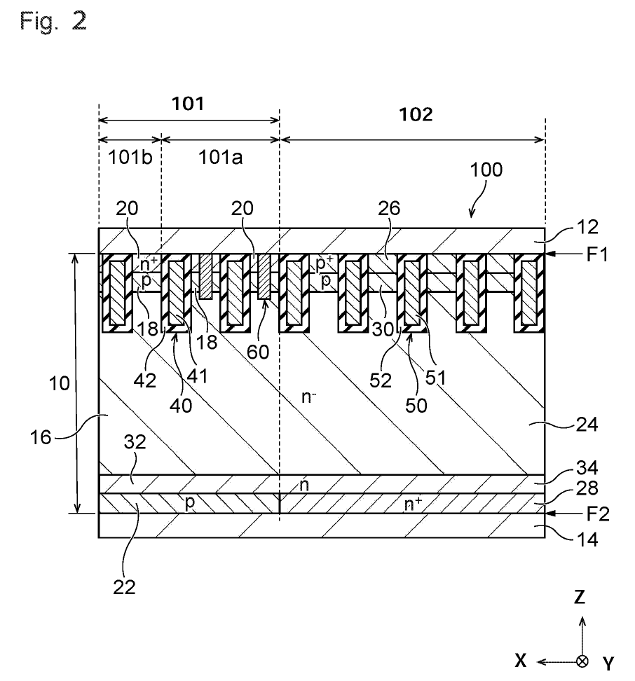

FIG. 1 is a schematic top view of the semiconductor device 100 according to this embodiment. FIG. 2 is a cross-sectional view along line AA' of FIG. 1.

In this specification, technical matters may be described using orthogonal coordinate axes of the x-axis, y-axis, and z-axis. In this specification, the x-direction parallel to the first surface F1 of the semiconductor layer 10 is referred to as the first direction. The y-direction, which is parallel to the first surface F1 and orthogonal to the first direction, is referred to as the second direction. The z-direction, which is orthogonal to the x-direction and y-direction and extends from the second surface F2 toward the first surface F1, is referred to as the third direction. In this specification, depth refers to the distance in the direction opposite to the third direction, from the first surface F1 toward the second surface F2. That is, shallow means a shorter distance in the direction from the first surface F1 toward the second surface F2.

The semiconductor device 100 according to this embodiment includes a transistor region 101, a diode region 102, and a first gate electrode pad 104. The transistor region 101 includes a first transistor region (also referred to as a boundary region) 101a and a second transistor region 101b.

The transistor region 101 is a region where an IGBT is formed as a transistor. That is, the transistor region 101 operates as an IGBT region.

The diode region 102 is a region where an RC diode is formed. The diode region 102 operates, for example, as a freewheeling diode. The freewheeling diode is, for example, a fast recovery diode (FRD).

The boundary region 101a is provided between the second transistor region 101b and the diode region 102. The boundary region 101a suppresses the interference between the operation of the transistor in the second transistor region 101b and the operation of the diode in the diode region 102, thereby preventing the degradation of the characteristics of the semiconductor device 100. That is, in the semiconductor device 100 according to this embodiment, the transistor in the second transistor region 101b is mainly used as an IGBT. The boundary region 101a operates as an IGBT region but is a region highly susceptible to interference from the operation of the diode in the diode region 102. An example of such interference is the inflow of carriers from the diode region 102 to the transistor region 101.

The semiconductor device 100 of the first embodiment includes a semiconductor layer 10, an upper electrode 12 (first electrode), and a lower electrode 14 (second electrode). The semiconductor layer 10 includes a first drift region 16 (first region), a base region 18 (second region), a cell emitter region 20 (third region), a collector region 22 (fourth region), a second drift region 24 (fifth region), a diode contact region 26 (sixth region), a cathode region 28 (seventh region), an anode region 30 (eighth region), a first buffer region 32 (ninth region), a second buffer region 34 (tenth region), a third electrode 41, a fourth electrode 51, and a first trench contact 60.

The semiconductor layer 10 has a first surface F1 and a second surface F2 opposite to the first surface F1. The semiconductor layer 10 is, for example, single-crystal silicon. The thickness of the semiconductor layer 10 is, for example, between 40 μm and 700 μm.

The width of the boundary region 101a in the first direction is within a range equivalent to the thickness of the semiconductor layer 10. For example, it is provided in a range where the probability of electron current diffused from the cathode region 28 reaching the second transistor region 101b, is high.

Here, an example of the configuration of the transistor region 101 will be described. The transistor region 101 includes a semiconductor layer 10, an upper electrode 12 (first electrode), and a lower electrode 14 (second electrode). The semiconductor layer 10 of the transistor region 101 includes a first drift region 16, a base region 18, a cell emitter region 20, a collector region 22, a first buffer region 32, and a third electrode 41. The boundary region 101a of the transistor region 101 differs from the second transistor region 101b in that it further includes a first trench contact 60.

The upper electrode 12 is provided on the side of the first surface F1 of the semiconductor layer 10. At least a part of the upper electrode 12 is in contact with the first surface F1 of the semiconductor layer 10.

In the transistor region 101, the upper electrode 12 functions as the emitter electrode of the IGBT. The upper electrode 12 is, for example, metal. That is, the upper electrode 12 is electrically connected to the cell emitter region 20.

The lower electrode 14 is provided on the side of the second surface F2 of the semiconductor layer 10. At least a part of the lower electrode 14 is in contact with the second surface F2 of the semiconductor layer 10. That is, the lower electrode 14 is electrically connected to the collector region 22.

The lower electrode 14 functions as the collector electrode of the IGBT in the transistor region 101. The lower electrode 14 is, for example, metal. The collector region 22 serves as a source of holes when the IGBT is in the on-state.

The first drift region 16 is an n- type semiconductor region. The first drift region 16 is provided between the base region 18 and the first buffer region 32 in the transistor region 101.

The first drift region 16 serves as the path for the on-current when the IGBT is in the on-state. The first drift region 16 depletes when the IGBT is in the off-state and functions to maintain the breakdown voltage of the IGBT.

The base region 18 is a p type semiconductor region. The base region 18 is provided between the first drift region 16 and the cell emitter region 20.

The base region 18 of the second transistor region 101b is in contact with the first gate insulating film 42. The base region 18 of the boundary region 101a is in contact with the first gate insulating film 42 and the first trench contact 60.

The depth of the base region 18 is, for example, 5 μm or less. An n type inversion layer is formed in the region of the base region 18 facing the third electrode 41 when the IGBT is in the on-state. That is, the base region 18 functions as the channel region of the transistor.

The base region 18 of the second transistor region 101b is in contact with the first gate insulating film 42. The base region 18 of the boundary region 101a is in contact with the first gate insulating film 42 and the first trench contact 60.

The n type impurity concentration of the cell emitter region 20 is higher than the n type impurity concentration of the first drift region 16. The cell emitter region 20 is electrically connected to the upper electrode 12. The cell emitter region 20 serves as a source of electrons when the transistor with the third electrode 41 is in the on-state.

The first buffer region 32 is, for example, an n type buffer layer. The n type impurity concentration of the first buffer region 32 is higher than the n type impurity concentration of the first drift region 16. The first buffer region 32 is provided between the first drift region 16 and the collector region 22. The first buffer region 32 functions as a layer to prevent the depletion layer spreading from the lower surface side of the base region 18, from reaching the collector region 22.

The cell emitter region 20 is an n+ type semiconductor region. The cell emitter region 20 is provided between the base region 18 and the first surface F1.

The cell emitter region 20 of the transistor region 101 is in contact with the first gate insulating film 42. The cell emitter region 20 of the boundary region 101a is in contact with the first gate insulating film 42 and the first trench contact 60.

The first gate trench 40 is provided on the side of the first surface F1 of the semiconductor layer 10. The first gate trench 40 is a groove provided in the semiconductor layer 10. The first gate trench 40 is part of the semiconductor layer 10.

The first gate trench 40 extends in the second direction parallel to the first surface F1. The first gate trench 40 has a stripe shape. A plurality of first gate trenches 40 are repeatedly arranged in the first direction orthogonal to the second direction.

The first gate trench 40 is in contact with the first drift region 16, the base region 18, and the cell emitter region 20. The first gate trench 40 penetrates the base region 18 and reaches the first drift region 16. The depth of the first gate trench 40 is, for example, 8 μm or less.

The third electrode 41 is a gate electrode and is provided in the first gate trench 40. The third electrode 41 is formed, for example, including metal. The third electrode 41 is electrically connected to the first gate electrode pad 104.

The first gate insulating film 42 is provided between the third electrode 41 and the semiconductor layer 10, and the upper electrode 12. That is, the first gate insulating film 42 is provided between the third electrode 41 and the upper electrode 12, between the third electrode 41 and the first drift region 16, between the third electrode 41 and the base region 18, and between the third electrode 41 and the cell emitter region 20. The first gate insulating film 42 is in contact with the upper electrode 12, the first drift region 16, the base region 18, and the cell emitter region 20. The first gate insulating film 42 is, for example, silicon oxide. Thus, the third electrode 41 is provided in the first gate trench 40 that penetrates the cell emitter region 20 and the base region 18 to reach the first drift region 16, and is covered by the insulating film 42 on the inner surface of the first gate trench 40 and the insulating film 42 on the first surface F1 side.

In the boundary region 101a, the first trench contact 60 is provided on the side of the first surface F1 of the semiconductor layer 10. The first trench contact 60 is within the semiconductor layer 10. That is, the first trench contact 60 is provided in the boundary region 101a, which extends into the transistor region 101 a predetermined distance from the boundary between the transistor region 101 and the diode region 102.

The first trench contact 60 extends in the second direction parallel to the first surface F1. The first trench contact 60 has a stripe shape. A plurality of first trench contacts 60 are repeatedly arranged in the first direction orthogonal to the second direction.

The first trench contact 60 is in contact with the first drift region 16, the base region 18, and the cell emitter region 20. The first trench contact 60 penetrates the base region 18 and the cell emitter region 20 to reach the first drift region 16.

The first trench contact 60 is, for example, Schottky bonded to the first drift region 16. The first trench contact 60 according to this embodiment is formed to be shallower than the first gate trench 40.

The first trench contact 60 is electrically connected to the upper electrode 12. The material of the first trench contact 60 may be different from the material of the upper electrode 12. Alternatively, the material of the first trench contact 60 may be the same as the material of the upper electrode 12. That is, the first trench contact 60 is formed of a material containing metal.

The end of the first trench contact 60 on the second surface F2 side is formed closer to the first surface F1 than the end of the third electrode 41 on the second surface F2 side. That is, the end of the third electrode 41 on the second surface F2 side is formed deeper than the end of the first trench contact 60 on the second surface F2 side.

Here, an example of the configuration of the diode region 102 will be described. The diode region 102 in the semiconductor layer 10 includes a second drift region 24, a diode contact region 26, a cathode region 28, an anode region 30, a second buffer region 34, and a fourth electrode 51.

In the diode region 102, the upper electrode 12 functions as the anode electrode of the diode. The upper electrode 12 is electrically connected to the diode contact region 26. The upper electrode 12 is also electrically connected to the anode region 30 via the diode contact region 26. Alternatively, the upper electrode 12 may be in direct contact with the anode region 30, in which case, for example, the upper electrode 12 and the anode region 30 have a Schottky junction.

In the diode region 102, the lower electrode 14 functions as the cathode electrode of the diode. The lower electrode 14 is in contact with the cathode region 28.

The second drift region 24 is provided between the anode region 30 and the first buffer region 32 in the diode region 102. The second drift region 24 has a thickness equivalent to that of the first drift region 16 in the third direction.

The n type impurity concentration of the second drift region 24 is lower than the n type impurity concentration of the cathode region 28. The second drift region 24 serves as the path for the on-current when the diode is in the on-state.

The diode contact region 26 is a p+ type semiconductor region. The diode contact region 26 is provided between the anode region 30 and the first surface F1.

The diode contact region 26 is in contact with the upper electrode 12. The diode contact region 26 is electrically connected to the upper electrode 12. The p type impurity concentration of the diode contact region 26 is higher than the p type impurity concentration of the anode region 30.

The cathode region 28 is an n+ type semiconductor region. The cathode region 28 forms part of the second surface F2. The cathode region 28 serves as a source of electrons when the diode is in the on-state. The cathode region 28 is in contact with the lower electrode 14.

The anode region 30 is a p type semiconductor region. The anode region 30 is provided between the second drift region 24 and the diode contact region 26. The anode region 30 serves as a source of holes when the diode is in the on-state. Furthermore, the depth of the anode region 30 is, for example, the same as the depth of the base region 18.

The second buffer region 34 has a thickness equivalent to that of the first buffer region 32 in the third direction. The n type impurity concentration of the second buffer region 34 is higher than the n type impurity concentration of the second drift region 24. The second buffer region 34 is provided between the second drift region 24 and the cathode region 28 in the third direction. For example, the second buffer region 34 functions as a layer to prevent the depletion layer spreading from the lower surface side of the base region 18, from reaching the cathode region 28.

The diode trench 50 is provided on the side of the first surface F1 of the semiconductor layer 10, in contact with the anode region 30. The diode trench 50 is a groove provided in the semiconductor layer 10. The diode trench 50 is part of the semiconductor layer 10.

The diode trench 50 extends in the second direction parallel to the first surface F1. The diode trench 50 has a stripe shape. A plurality of diode trenches 50 are repeatedly arranged in the first direction orthogonal to the second direction.

The diode trench 50 penetrates the anode region 30 and reaches the second drift region 24. The diode trench 50 is in contact with the second drift region 24, the anode region 30, and the diode contact region 26. The depth of the diode trench 50 is, for example, 8 μm or less.

The fourth electrode 51 is provided in the diode trench 50. The fourth electrode 51 is, for example, metal. The diode trench 50 can be a dummy trench that does not fix the fourth electrode 51 to a specific potential. Alternatively, a voltage can be applied to the fourth electrode 51.

The diode insulating film 52 is provided between the fourth electrode 51 and the semiconductor layer 10, and the upper electrode 12. The diode insulating film 52 is provided between the fourth electrode 51 and the upper electrode 12, between the fourth electrode 51 and the second drift region 24, between the fourth electrode 51 and the diode contact region 26, and between the fourth electrode 51 and the anode region 30.

The diode insulating film 52 is in contact with the upper electrode 12, the second drift region 24, the diode contact region 26, and the anode region 30. The diode insulating film 52 is, for example, silicon oxide. Thus, the fourth electrode 51 is provided in the diode trench 50 that penetrates the diode contact region 26 and the anode region 30 to reach the second drift region 24, and is covered by the diode insulating film 52 on the inner surface of the diode trench 50 and the diode insulating film 52 on the first surface F1 side.

Here, an example of the operation of the semiconductor device 100 and the effect of the first trench contact 60 will be described. A predetermined first gate voltage is applied to the first gate electrode pad 104 at a predetermined timing. After the first turn-on voltage is applied to the first gate electrode pad 104, a predetermined first turn-off voltage is applied to the first gate electrode pad 104.

An emitter voltage is applied to the upper electrode 12 in the transistor region 101. The emitter voltage is, for example, 0V. A collector voltage is applied to the lower electrode 14. The collector voltage is, for example, between 200V and 6500V.

In the off-state of the IGBT, the first turn-off voltage is applied to the first gate electrode pad 104. Therefore, the first turn-off voltage is also applied to the third electrode 41. The first turn-off voltage is a voltage below the threshold voltage at which the transistor with the third electrode 41 does not turn on, and is, for example, 0V or a negative voltage. In the off-state, no n type inversion layer is formed in the base region 18 facing the third electrode 41 and in contact with the first gate insulating film 42.

On the other hand, when the first turn-on voltage is applied to the first gate electrode pad 104, the first gate voltage becomes the first turn-on voltage, and the first turn-on voltage is also applied to the third electrode 41. The application of the first turn-on voltage turns on the transistor with the third electrode 41. In the on-state, an n type inversion layer is formed in the base region 18 facing the third electrode 41 and in contact with the first gate insulating film 42. As a result, the IGBT becomes conductive.

On the other hand, when the diode region 102 conducts, electron current flows from the cathode region 28 to the anode region 30, and hole current flows from the anode region 30 to the cathode region 28.

If the first trench contact 60 is not present, holes are injected into the boundary region 101a from the diode region 102 because the base region 18 of the transistor region 101 is at the same potential as the anode region 30. This increases the hole concentration in the semiconductor layer 10. As a result, the time until the carriers disappear during the turn-off of the diode in the diode region 102 becomes longer.

In contrast, in the semiconductor device 100 according to this embodiment, the inflowing electron current is absorbed by the first trench contact 60 that penetrates the base region 18. This shortens the time until the carriers disappear during the turn-off of the diode.

Furthermore, if the first trench contact 60 is deeper than the first gate trench 40, the contact area between the first trench contact 60 and the first drift region 16 increases, which shortens the time until the carriers disappear during the turn-off of the diode in the diode region 102. In other words, the electron discharge effect increases, enabling faster recovery operation.

In addition, the potential of the first trench contact 60 is the same as that of the cell emitter region 20 (0V) in the blocking state of the RC-IGBT. The third electrode 41 in the first gate trench 40 is, for example, 0V or a negative voltage. As a result, the mesa region sandwiched between the first gate trench 40 trenches has a value close to 0V. Therefore, if the first trench contact 60 is shallower than the first gate trench 40, the electric field between the end of the first trench contact 60 on the lower electrode 14 side and the lower electrode 14 does not depend on the depth of the first trench contact 60. As a result, in the blocking state of the semiconductor device 100, if the first trench contact 60 is shallower than the first gate trench 40, the increase in leakage current is suppressed.

On the other hand, if the first trench contact 60 is deeper than the first gate trench 40, the 0V point approaches the second surface F2 side. In addition, a collector voltage of, for example, between 200V and 6500V is applied to the lower electrode 14. Therefore, the electric field between the end of the first trench contact 60 on the lower electrode 14 side and the lower electrode 14 increases, which may increase the leakage current. Therefore, the length of the first trench contact 60 according to this embodiment can be changed according to the purpose.

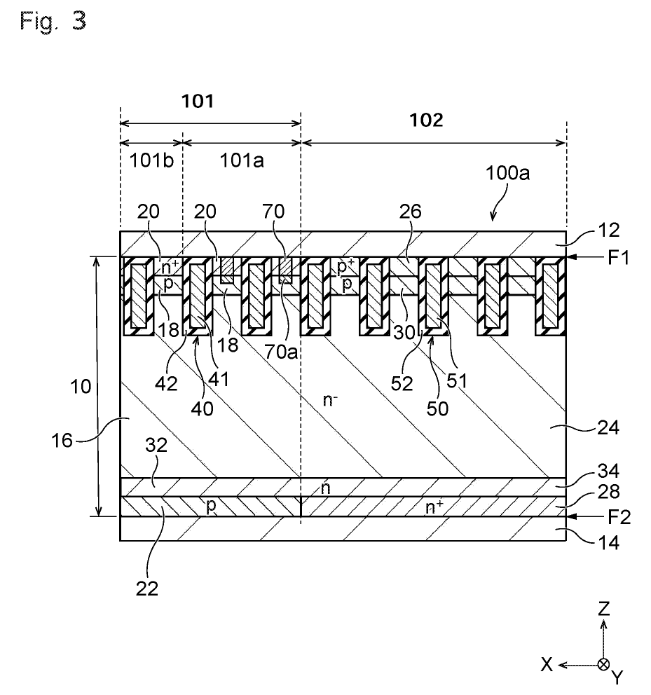

FIG. 3 is a schematic cross-sectional view of a part of a semiconductor device 100a according to a comparative example. FIG. 3 is a cross-sectional view along line AA' of FIG. 1. The semiconductor device 100a according to the comparative example differs from the semiconductor device 100 according to the first embodiment in that the second trench contact 70 does not penetrate the base region 18. The differences from the semiconductor device 100 according to the first embodiment will be described below.

As shown in FIG. 3, the second trench contact 70 penetrates the cell emitter region 20 but does not penetrate the base region 18. The second trench contact 70 is connected to the upper electrode 12. The second trench contact 70 is, for example, Schottky bonded to the base region 18.

The material of the second trench contact 70 may be different from the material of the upper electrode 12. Alternatively, the material of the second trench contact 70 may be the same as the material of the upper electrode 12.

A p+ type semiconductor region is provided at the end of the second trench contact 70 as the second plug region 70a. The second plug region 70a corresponds, for example, to a p-contact layer. It is also possible not to provide the second plug region 70a.

During turn-off, the provision of the second trench contact 70 reduces the resistance of the base region 18, making it easier to extract carriers. Additionally, the second plug region 70a can improve the breakdown tolerance, such as latch-up tolerance.

On the other hand, when the potential of the upper electrode 12 becomes higher than the potential of the lower electrode 14 and the diode region 102 conducts, electron current flows from the cathode region 28 to the anode region 30. When the electron current reaches the anode region 30, conductivity modulation occurs, and hole current flows from the anode region 30. As mentioned above, since the base region 18 of the transistor region 101 is at the same potential as the anode region 30, holes are injected into the boundary region 101a from the diode region 102. This increases the hole concentration in the boundary region 101a.

In contrast, the first trench contact 60 according to this embodiment penetrates the base region 18 as described above. Thus, as described above, it absorbs the diffused electron current as the potential of the upper electrode 12 rises. Therefore, hole injection is more efficiently suppressed, making it possible to shorten the width of the boundary region 101a in the first direction.

As described above, according to this embodiment, the first trench contact 60, which is connected to the upper electrode 12 and penetrates the base region 18, is provided in the boundary region 101a adjacent to the diode region 102. This allows the absorption of electron current diffused from the cathode region 28 as the potential of the upper electrode 12 rises. Therefore, it is possible to shorten the time for the carriers to disappear during the turn-off of the diode region 102.

### Second Embodiment

The semiconductor device according to the second embodiment differs from the semiconductor device according to the first embodiment in that a second trench contact 70 is further provided in the transistor region 101. The differences from the semiconductor device according to the first embodiment will be described below.

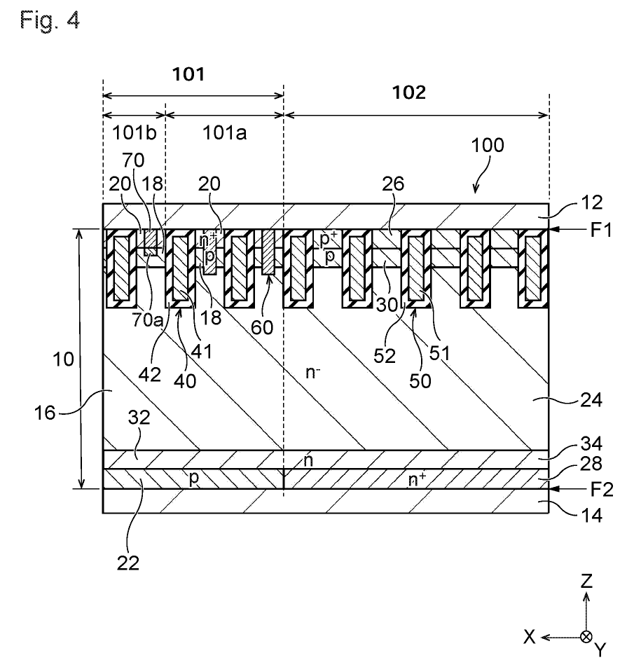

FIG. 4 is a schematic cross-sectional view of a part of the semiconductor device 100 according to the second embodiment. FIG. 4 is a cross-sectional view along line AA' of FIG. 1.

As shown in FIG. 4, a second trench contact 70 is provided in the second transistor region 101b of the transistor region 101. As described above, the second trench contact 70 penetrates the cell emitter region 20 but does not penetrate the base region 18. The second trench contact 70 is connected to the upper electrode 12. The second trench contact 70 is, for example, Schottky bonded to the base region 18.

The material of the second trench contact 70 may be different from the material of the upper electrode 12. Alternatively, the material of the second trench contact 70 may be the same as the material of the upper electrode 12. That is, the second trench contact 70 is formed to include metal.

A p+ type second plug region 70a is provided at the end of the second trench contact 70. The second plug region 70a corresponds, for example, to a p-contact layer. It is also possible not to provide the second plug region 70a.

Thus, the IGBT in the second transistor region 101b, during turn-off, reduces the resistance of the base region 18 by providing the second trench contact 70, making it easier to extract carriers. Additionally, the second plug region 70a can improve the breakdown tolerance, such as latch-up tolerance.

As described above, according to this embodiment, a second trench contact 70 that penetrates the cell emitter region 20 but does not penetrate the base region 18 is provided in the transistor region 101. This reduces the resistance of the base region 18 during turn-off, making it easier to extract carriers. Additionally, the second plug region 70a can improve the breakdown tolerance, such as latch-up tolerance. Furthermore, the first trench contact 60 in the boundary region 101a absorbs the electron current diffused from the base region 18. Therefore, the second trench contact 70 can function while suppressing the influence of the diffused electron current.

### Third Embodiment

The semiconductor device according to the third embodiment differs from the semiconductor device according to the first embodiment in that an n+ type first plug region 60a is further provided at the end of the first trench contact 60 in the boundary region 101a. The differences from the semiconductor device according to the first embodiment will be described below.

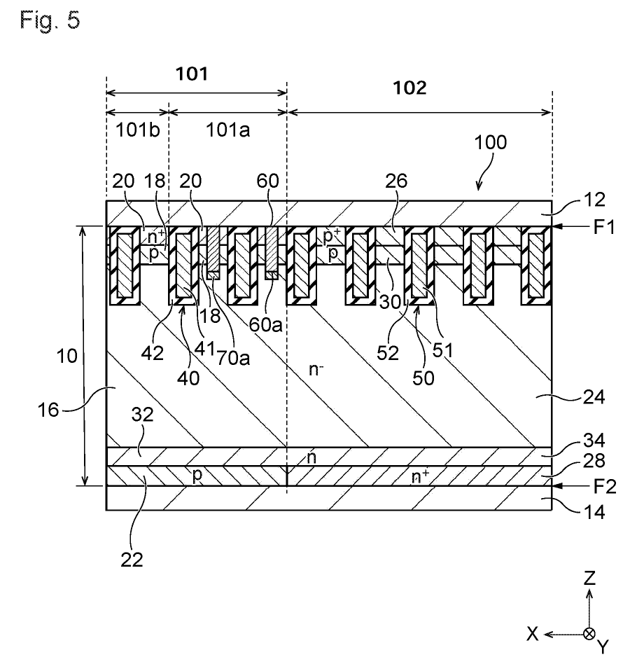

FIG. 5 is a schematic cross-sectional view of a part of the semiconductor device 100 according to the third embodiment. FIG. 5 is a cross-sectional view along line AA' of FIG. 1.

As shown in FIG. 5, an n+ type semiconductor region is further provided as the first plug region 60a at the end of the first trench contact 60 in the boundary region 101a. This improves the breakdown tolerance at the end of the first trench contact 60.

### Fourth Embodiment

The semiconductor device according to the fourth embodiment differs from the semiconductor device according to the first embodiment in that the lengths of the first trench contacts 60 and 62 in the boundary region 101a are different. The differences from the semiconductor device according to the first embodiment will be described below.

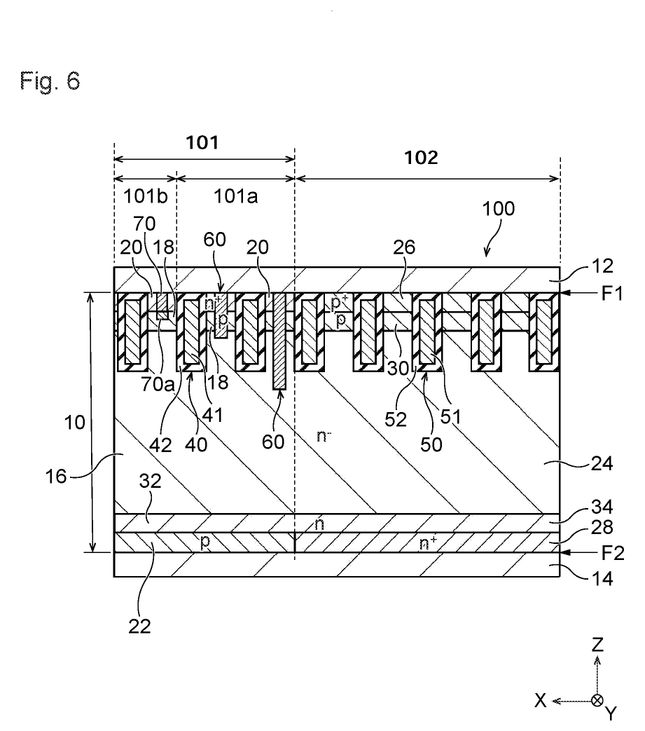

FIG. 6 is a schematic cross-sectional view of a part of the semiconductor device 100 according to the fourth embodiment. FIG. 6 is a cross-sectional view along line AA' of FIG. 1.

As shown in FIG. 6, with reference to FIG. 1, a plurality of first trench contacts 60 are formed in the boundary region 101a, which extends into the transistor region 101 a predetermined distance from the boundary between the transistor region 101 and the diode region 102, in the first direction orthogonal to the boundary along the first surface F1. Additionally, at least one of the first trench contacts 60 is formed longer than the other first trench contacts 60 in the boundary region 101a. This longer first trench contact 60 is formed longer on the second surface F2 side than the first gate trench 40. That is, the end of the longer first trench contact 60 on the second surface F2 side is formed closer to the second surface F2 than the end of the third electrode 41 on the second surface F2 side.

Additionally, the longer first trench contact 60 is formed on the diode region 102 side of the first trench contacts 60. The length of the first trench contacts 60 can be set considering the leakage current as described above.

By making the first trench contact 60 longer, it is possible to absorb more diffused electron current as the potential of the upper electrode 12 rises. Additionally, by making the length of the first trench contact 60 on the diode region 102 side longer than the first trench contacts 60, it is possible to absorb the diffused electron current more efficiently. This further shortens the time until the carriers disappear during the turn-off of the diode in the diode region 102 and allows the width of the boundary region 101a in the first direction to be narrower.

### (Fifth Embodiment)

The semiconductor device according to the fifth embodiment differs from the semiconductor device according to the first embodiment in that a third trench contact 80 is further provided in the diode region 102. The differences from the semiconductor device according to the first embodiment will be described below.

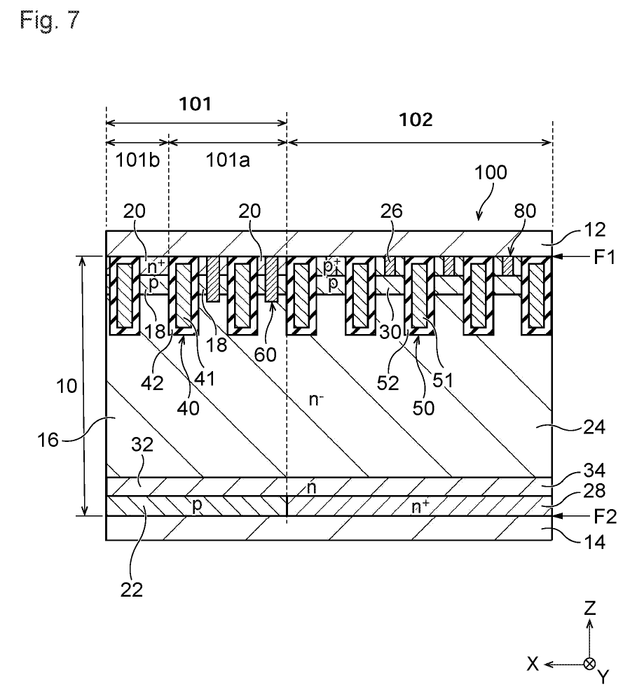

FIG. 7 is a schematic cross-sectional view of a part of the semiconductor device 100 according to the fifth embodiment. FIG. 7 is a cross-sectional view along line AA' of FIG. 1.

As shown in FIG. 7, a third trench contact 80 is provided in the diode region 102 in the boundary region 101a. The third trench contact 80 penetrates the diode contact region 26 but does not penetrate the anode region 30.

The material of the third trench contact 80 may be different from the material of the upper electrode 12. Alternatively, the material of the third trench contact 80 may be the same as the material of the upper electrode 12. That is, the third trench contact 80 is formed to include metal.

The third trench contact 80 is also connected to the upper electrode 12. The third trench contact 80 is, for example, Schottky bonded to the anode region 30. It is also possible to provide a p+ type semiconductor region as the third plug region at the end of the third trench contact 80.

By providing the third trench contact 80, the resistance of the anode region 30 is reduced, making it easier to extract carriers (e.g., electrons). It is also possible to provide the third trench contact 80 in the first to fourth embodiments.

Several embodiments of the present invention have been described, but these embodiments are presented as examples and are not intended to limit the scope of the invention. These novel embodiments can be implemented in various other forms, and various omissions, substitutions, and changes can be made without departing from the spirit of the invention. These embodiments and their modifications are included within the scope and spirit of the invention and are included within the scope of the invention as described in the claims and their equivalents.

What is claimed is:

1. A semiconductor device having a transistor region and a diode region, comprising:
a semiconductor layer comprising a first surface and a second surface opposite to the first surface;
a first electrode;
a second electrode, wherein
the transistor region of the semiconductor layer comprises:
a first region of a first conductivity type provided between the first surface and the second surface of the semiconductor layer;
a second region of a second conductivity type provided between the first surface and the first region of the semiconductor layer;
a third region of the first conductivity type provided between the second region and the first surface of the semiconductor layer, and electrically connected to the first electrode;
a fourth region of the second conductivity type provided between the second surface and the first region of the semiconductor layer, and electrically connected to the second electrode;
a first trench contact electrically connected to the first electrode, and penetrating through the third region and the second region to reach the first region; and
a third electrode provided in a gate trench penetrating through the third region and the second region to reach the first region, covered by an insulating film on the inner surface of the gate trench and an insulating film on the first surface side.

2. The semiconductor device according to claim 1, wherein the first trench contact is provided within a boundary region that is between the gate trench and the diode region.

3. The semiconductor device according to claim 2, wherein the end of the first trench contact on the second surface side is closer to the first surface than the end of the third electrode on the second surface side.

4. The semiconductor device according to claim 2, wherein the end of the first trench contact on the second surface side is closer to the second surface than the end of the third electrode on the second surface side.

5. The semiconductor device according to claim 2, wherein a plurality of the trench contacts including the first trench contact are formed in the boundary region, and a depth of the plurality of trench contacts decreases as they move away from the diode region.

6. The semiconductor device according to claim 5, wherein some of the plurality of trench contacts have ends on the second surface side that are closer to the second surface than the ends of the third electrode on the second surface side.

7. The semiconductor device according to claim 2, wherein the boundary region is between the gate trench and the diode region in a first direction that is parallel to the first and second surfaces, and a width of the boundary region in the first direction is less than or equal to a distance between the first surface and the second surface.

8. The semiconductor device according to claim 1, wherein the first trench contact and the first region are Schottky-bonded.

9. The semiconductor device according to claim 1, wherein a first plug region of the first conductivity type with a higher carrier concentration than the first region is further provided at the end of the first trench contact on the second surface side.

10. The semiconductor device according to claim 1, further comprising a second trench contact electrically connected to the first electrode, and penetrating through the third region to reach the second region in the transistor region excluding the boundary region, and a second plug region of the second conductivity type with a higher carrier concentration than the second region provided at the end of the second trench contact on the second surface side.

11. The semiconductor device according to claim 1, wherein the diode region of the semiconductor layer comprises:
a fifth region of the first conductivity type provided between the first surface and the second surface of the semiconductor layer;
a sixth region of the second conductivity type provided between the first region and the first surface of the semiconductor layer, and electrically connected to the first electrode;
a seventh region of the first conductivity type provided between the second surface and the first region of the semiconductor layer, and electrically connected to the second electrode; and
a fourth electrode provided in a diode trench penetrating through the sixth region to reach the fifth region, covered by an insulating film on the inner surface of the diode trench and an insulating film on the first surface side.

12. The semiconductor device according to claim 11, wherein the diode region further comprises an eighth region of the second conductivity type with a lower carrier concentration than the sixth region, provided between the fifth region and the sixth region.

13. The semiconductor device according to claim 12, wherein the diode region further comprises a third trench contact electrically connected to the first electrode, and penetrating through the sixth region.

14. The semiconductor device according to claim 13, wherein the transistor region further comprises a ninth region of the first conductivity type with a higher carrier concentration than the first region, provided between the fourth region and the first region.

15. The semiconductor device according to claim 14, wherein the diode region further comprises a tenth region of the first conductivity type with a higher carrier concentration than the fifth region, provided between the fifth region and the seventh region.

16. The semiconductor device according to claim 15, wherein an insulated gate bipolar transistor is formed in the transistor region.

17. The semiconductor device according to claim 16, wherein a freewheeling diode is formed in the diode region.

18. The semiconductor device according to claim 17, wherein during the on-state of the insulated gate bipolar transistor, an inversion layer of the first conductivity type is formed in the second region in contact with the insulating film.

19. The semiconductor device according to claim 18, wherein during the off-state of the insulated gate bipolar transistor, the voltage applied to the third electrode is 0 volts or less.

20. A semiconductor device having a transistor and a diode, comprising:
a semiconductor layer comprising a first surface and a second surface opposite to the first surface and a transistor region in which the transistor is formed and a diode region in which the diode is formed;
a first electrode in contact with the first surface of the semiconductor layer;
a second electrode in contact with the second surface of the semiconductor layer, wherein
the semiconductor layer comprises:
a first region of a first conductivity type between the first surface and the second surface of the semiconductor layer in the transistor region and the diode region;
a base region of a second conductivity type in the transistor region between the first surface and the first region;
an emitter region of the first conductivity type in the transistor region between the base region and the first surface of the semiconductor layer, and electrically connected to the first electrode;
a collector region of the second conductivity type in the transistor region between the second surface and the first region, and electrically connected to the second electrode;
a plurality of gate trenches in the transistor region, each of the gate trenches extending inwardly from the first surface through the emitter region and the base region to reach the first region and having an electrode surrounded by an insulating film that is on the inner surface of the corresponding gate trench and the first surface;
an anode region of the second conductivity type in the diode region between the first surface and the first region;
a contact region of the second conductivity type in the diode region between the anode region and the first surface of the semiconductor layer, and electrically connected to the first electrode;
a cathode region of the first conductivity type in the diode region between the second surface and the first region, and electrically connected to the second electrode;
a plurality of diode trenches in the diode region, each of the diode trenches extending inwardly from the first surface through the contact region and the anode region to reach the first region and having an electrode surrounded by an insulating film that is on the inner surface of the corresponding diode trench and the first surface; and
a trench contact between one of the gate trenches that is closest to the diode region and one of the diode trenches that is closest to the transistor region, the trench contact in contact with the first electrode and extending inwardly from the first surface through the emitter region and the base region to reach the first region.
